(19) United States
(12) Patent Application Publication
(10) Pub. No.: US 2025/0040023 A1
(43) Pub. Date: Jan. 30, 2025

(54) ELECTRON BEAM AND DROPLET-BASED EXTREME ULTRAVIOLET LIGHT SOURCE DEVICE

(71) Applicant: UNIVERSITY-INDUSTRY COOPERATION GROUP OF KYUNG HEE UNIVERSITY, Gyeonggi-do (KR)

(72) Inventors: Kyu Chang PARK, Seoul (KR); Sung Tae YOO, Seoul (KR)

(21) Appl. No.: 18/690,661

(22) PCT Filed: Sep. 7, 2022
(86) PCT No.: PCT/KR2022/013487

§ 371 Date: Oct. 2, 2024

(30) Foreign Application Priority Data
Sep. 10, 2021 (KR) 10-2021-0121130

(51) Int. Cl. H05G 2/00

(52) U.S. Cl. CPC H05G 2/0035

(57) ABSTRACT

There is provided a light source device for outputting an extreme ultraviolet light source based on an electron beam and a metal droplet, comprising: a chamber; an electron beam emission unit including a cathode electrode and a plurality of emitters, each of which contains a carbon-based material and which are arranged over the cathode electrode in such a manner as to be spaced apart from each other, the electron beam emission unit generating an electron beam within the chamber; an anode electrode positioned within the chamber, but in a manner that is spaced apart from the electron beam emission unit; and a droplet generation device injecting a metal droplet into a space between the electron beam emission unit and the anode electrode within the chamber, wherein, within the chamber, the metal droplet is ionized by the electron beam proceeding toward the anode electrode, thereby generating plasma, and extreme ultraviolet is generated from the plasma.

### TECHNICAL FIELD

The present disclosure relates to an electron beam-based and droplet-based extreme ultraviolet light source device, and more particularly, to an apparatus for outputting an extreme ultraviolet light source using an electron beam and a droplet.

### BACKGROUND ART

Extreme ultraviolet (EUV) is an electromagnetic wave with a wavelength ranging approximately from 10 nm to 100 nm, falling between X-ray and deep ultraviolet (DUV). In recent years, a lot of research has been focused on the development of compact extreme ultraviolet light devices for applications dealing with an extreme ultraviolet field.

For example, extreme ultraviolet lithography equipment is being used in the nanometer-scale micropatterning process for semiconductor manufacturing. However, current extreme ultraviolet lithography equipment is based on high-power lasers and is only released as products from a specific overseas company. In particular, since this extreme ultraviolet lithography equipment is laser-based, it is very expensive, has a complex internal structure, occupies a large volume, and is difficult to maintain due to the large amounts of debris generated by the laser, which is bound to be very high power depending on its output characteristics.

### DISCLOSURE

### Technical Problem

One object of the present disclosure, which is made to address the above-mentioned problem in the prior art, is to provide an extreme ultraviolet light source technology that has a simple internal structure, a compact size, and can lower manufacturing costs.

Another object of the present disclosure is to provide an extreme ultraviolet light source technology that is advantageous for maintenance by reducing debris by using a low-power electron beam compared to a laser.

Still another object of the present disclosure is to provide an extreme ultraviolet light source technology that utilizes a plurality of electron beams in a more efficient manner, resulting in improved light output.

However, the present disclosure is not limited to the above-mentioned objects. From the following description, other objects not mentioned would be readily understandable to a person of ordinary skill in the art to which the present disclosure pertains.

### Technical Solution

In order to address the above-mentioned objects, there is provided a light source device according to one embodiment of the present disclosure for outputting an extreme ultraviolet light source based on an electron beam and a metal droplet, comprising: a chamber; an electron beam emission unit including a cathode electrode and a plurality of emitters, each of which contains a carbon-based material and which are arranged over the cathode electrode in such a manner as to be spaced apart from each other, the electron beam emission unit generating an electron beam within the chamber; an anode electrode positioned within the chamber, but in a manner that is spaced apart from the electron beam emission unit; and a droplet generation device injecting a metal droplet into a space between the electron beam emission unit and the anode electrode within the chamber, wherein, within the chamber, the metal droplet is ionized by the electron beam proceeding toward the anode electrode, thereby generating plasma, and extreme ultraviolet is generated from the plasma.

A plurality of said electron beam emission units are provided, and each of the electron beams generated by the plurality of said electron beam units may proceed at a different angle or in a different direction toward the at least one anode electrode, wherein each of the electron beams may be output one by one or a plurality of electron beams may be output simultaneously.

Each of the electron beam emission units may be arranged on one side within the chamber, and the anode electrode may be arranged on the other side within the chamber where an exit for the extreme ultraviolet light source is located.

The anode electrode may be arranged on the other side in the chamber in a manner that is positioned in the vicinity of the exit, with the exit in the middle of the anode electrode, and the anode electrode may have an opening corresponding to the exit.

One side and the other side in the chamber may have respective shapes of an arch that face each other, and the anode electrode may have a shape that corresponds to the arch shape of the other side in the chamber.

The light source device according to one embodiment of the present disclosure may further include a reflection layer arranged in the vicinity of the respective electron beam emission units on one side in the chamber, but also in the spaces between said respective electron beam emission units, to reflect the extreme ultraviolet.

One side and the other side within the chamber may have respective shapes of an arch that face each other, and the reflection layer may have a shape that corresponds to the arch shape of one side within the chamber.

The anode electrode may serve for intermediate focus (IF) of a multiplicity of extreme ultraviolet light sources that are generated by the electron beams and pass through the opening in the anode electrode.

The plurality of emitters may have pointed emitter tips, and the carbon-based material contained in the emitters may include carbon nanotubes.

The electron beam emission unit may further include a gate electrode arranged over the plurality of emitters in a manner that is spaced apart therefrom.

A portion, facing the plurality of emitters, of the gate electrode may have a mesh structure of a conductive material.

The electron beam emission unit may further include at least one focusing electrode positioned over the gate electrode in a manner that is spaced apart from the gate electrode, and focusing the electron beam by a negative voltage being applied to the gate electrode.

The focusing electrode may include a first focusing electrode and a second focusing electrode arranged over the first focusing electrode in a manner that is spaced apart from the first focusing electrode. The first and second focusing electrodes may have respective openings facing each other, in such a manner as to allow the electron beams to pass through, and the opening in the second focusing electrode may be smaller than the opening in the first focusing electrode.

### Advantageous Effects

According to the present disclosure, with the configuration as described above, an extreme ultraviolet (EUV) light source is generated based on an electron beam but using an anode electrode that is formed separately from an electron beam emission unit. Therefore, the present disclosure provides the advantage of achieving a simple inner structure, a compact size, and a low manufacturing cost.

In addition, the present disclosure has the advantage of reducing the adverse effects on the anode electrode by utilizing an electron beam with a lower power compared to a laser, thereby reducing debris and the like, which is advantageous for maintenance, and has the effect of increasing the amount of extreme ultraviolet light using a plurality of electron beams.

In addition, according to the present disclosure, a reflection function and a light collecting function with respect to an ultraviolet light are extreme source simultaneously performed in a complementary manner through the structure of a reflection layer in the shape of an arch on one side in a chamber, and through the structure of the anode electrode in the shape of an arch on the other side in the chamber. Thus, the present disclosure provides the advantage of improving output of the amount of extreme ultraviolet light.

The present disclosure is not limited to the above-mentioned effects. From the following description, other effects not mentioned would be readily understandable to a person of ordinary skill in the art to which the present disclosure pertains.

### DESCRIPTION OF DRAWINGS

FIGS. 1 to 3 are views each illustrating a configuration of an extreme ultraviolet light source device 10 according to an embodiment of the present disclosure.

FIG. 4 is a view illustrating a detailed configuration of an electron beam emission unit 200.

FIGS. 5(a) and 5(b) are a perspective view and a cross-sectional view, respectively, each illustrating one embodiment of the electron beam emission unit 200.

FIG. 6 is a cross-sectional view illustrating another example of the electron beam emission unit 200, where focusing electrodes 251, 252 are added to the implementation example of the electron beam emission unit in FIG. 4.

### DESCRIPTION OF THE REFERENCE NUMERALS IN THE DRAWINGS

10: Extreme ultraviolet light source device 100: Chamber
110: Exit 200: Electron beam emission unit
210: Cathode electrode 220: Electric field emission substrate
230: Emitter 240: Gate electrode
241: Mesh structure 242: Support body
251, 252: Focusing electrode 261, 262, 263: Insulation layer
300: Anode electrode 400: Droplet generation device
500: Reflection layer

### BEST MODE

The objects of the present disclosure, the means of achieving the objects thereof, and the advantageous effects thereof will be apparent from the following detailed description, which is provided with reference to the accompanying drawings in sufficient detail to enable a person having ordinary skill in the art to which the present disclosure pertains to practice the present disclosure. In addition, in a case where it is determined that a specific description of a known art related to the present disclosure would unnecessarily obscure the nature and gist of the present disclosure, the detailed description thereof is omitted from description of the present disclosure.

Unless otherwise defined, all terms used in the present disclosure should be construed as having meanings commonly understandable to a person having ordinary skill in the art to which the present disclosure pertains. In addition, unless otherwise explicitly and specifically defined, the terms as defined in commonly used dictionaries should not be construed ideally or excessively.

A preferred embodiment of the present disclosure will be described in detail below with reference to the accompanying drawings.

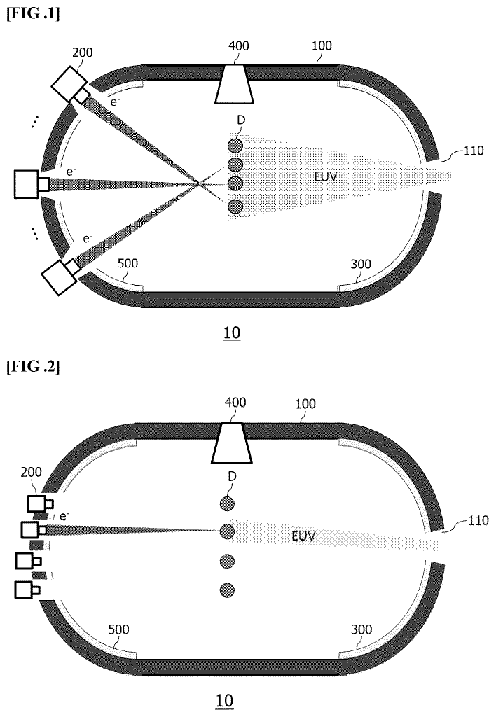

FIGS. 1 to 3 are views each illustrating a configuration of an extreme ultraviolet light source device 10 according to an embodiment of the present disclosure. However, FIG. 1 illustrates a case where a multiplicity of electron beam emission units 200 simultaneously emit electron beam beams. FIGS. 2 and 3 illustrate a case where the multiplicity of electron beam emission units 200 emit electron beams in a different direction than in FIG. 1. In particular, FIGS. 2 and 3 each illustrate a case where the multiplicity of electron beam emission units 200 sequentially emit electron beams one by one.

With reference to FIG. 1, the extreme ultraviolet light source device 10 according to one embodiment of the present disclosure includes a chamber 100, the electron beam emission unit 200 positioned within the chamber 100, an anode electrode 300, and a droplet generation device 400. For example, the extreme ultraviolet light source device 10 may be used as a lithography apparatus during a micropatterning process for manufacturing semiconductors, but is not limited thereto.

The chamber 100 keeps plasma inside. Such plasma is generated by ionization of a metal droplet upon incidence of an electron beam. For convenience, a region of a space within the chamber 100, where plasma is kept, is referred to as a “plasma region.” The chamber 100 may include an exit 110 through which an extreme ultraviolet (EUV) light source, which occurs in the plasma region, is outputted. The chamber 100 may be maintained under vacuum inside.

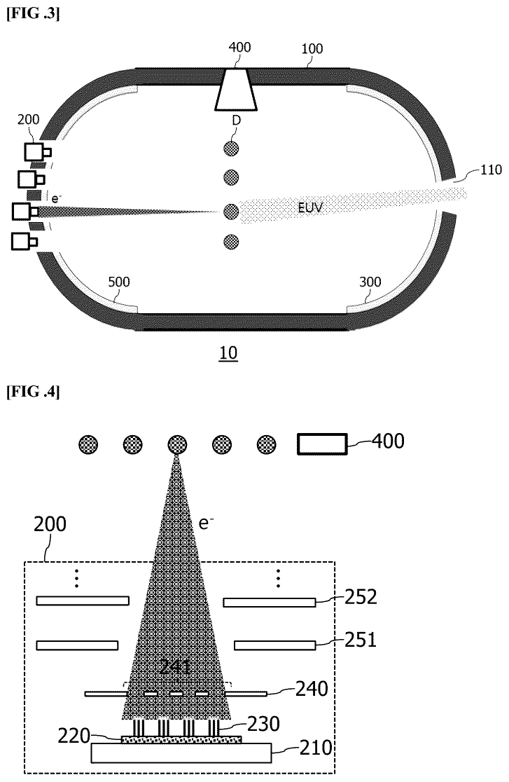

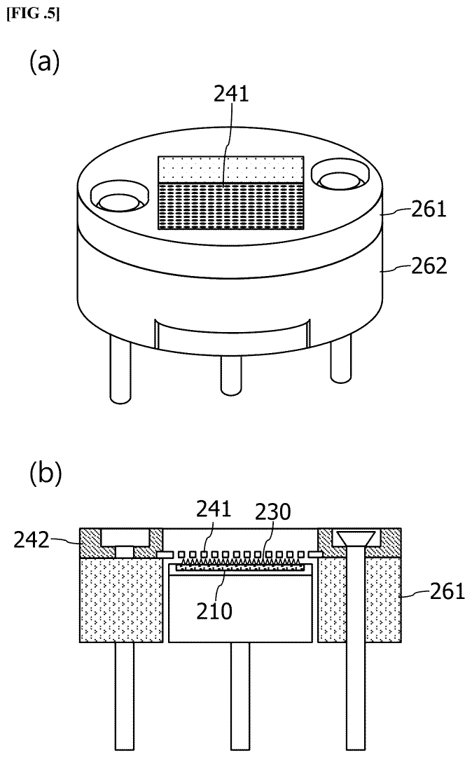

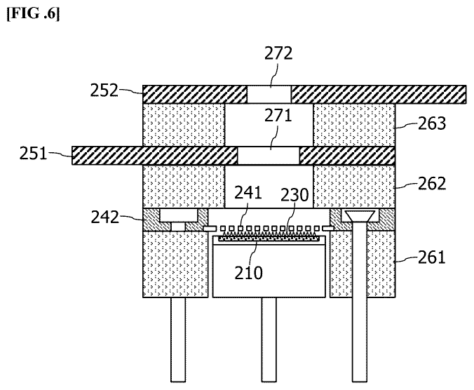

FIG. 4 is a view illustrating a detailed configuration of the electron beam emission unit 200. FIGS. 5(a) and 5(b) are a perspective view and a cross-sectional view, respectively, each illustrating an implementation example of the electron beam emission unit 200. FIG. 6 is a cross-sectional view illustrating another implementation example of the electron beam emission unit 200, where focusing electrodes 251, 252 are added to the implementation example of the electron beam emission unit 200 in FIG. 4.

The electron beam emission unit 200 is configured to generate and emit an electron beam e⁻. At this point, the electron beam emission unit 200 is based on a carbon-based emitter 230 that emits electrons by an electric field, instead of being based on a laser.

The electron beam emission unit 200 is positioned within the chamber 100 and irradiates an electron beam toward the anode electrode 300 that is arranged to be spaced apart from the electron beam emission unit 200 within the chamber 100. With reference to FIGS. 4 to 6, the electron beam emission unit 200 includes a cathode electrode 210, a plurality of emitters 230 positioned over the cathode electrode 210, and a gate electrode 240 positioned over the plurality of emitters 230 in a manner that is spaced apart from the plurality of emitters 230.

The cathode electrode 210 and the anode electrode 300 contain a conductive material, and, normally, are used as a negative electrode and a positive electrode, respectively. For example, the cathode electrode 210 and the anode electrode 300 each may contain a metal, such as Al, Au, Ni, Ti, or Cr; transparent conductive oxide (TCO), such as indium tin oxide (ITO), indium zinc oxide (IZO), aluminum zinc oxide (AZO), or indium zinc tin oxide (IZTO); a conductive polymer; graphene; or similar material, but are not limited thereto.

In the prior art, in normal cases, a cathode electrode, an emitter, and an anode electrode are provided together within an electron beam emission unit. In these cases, the electron beam emission unit may become large in volume. In contrast, according to the present disclosure, the anode electrode 300 is not provided within the electron beam emission unit 200. Instead, the anode electrode 300 is configured to be separately provided in a manner that is spaced apart from the electron beam emission unit 200 within the chamber 100. Accordingly, the present disclosure provides the advantage that, although the multiplicity of electron beam emission units 200 are provided, the total volume thereof can be reduced.

In addition, according to the present disclosure, the multiplicity of electron beam emission units 200 can emit electron beams using a common anode electrode 300 separately provided within the chamber 100. Therefore, the present disclosure provides the advantage of achieving a simpler inner structure, a more compact size, and a lower manufacturing cost than in a case where a cathode electrode, an emitter, and an anode electrode are provided together within an electron beam emission unit.

The plurality of emitters 230 are configured to emit electrons, supplied from the cathode electrode 210, toward the anode electrode 300. The emitter 230 may be configured as a pointed emitter tip or as a flat emitter layer. At this point, in addition to the acicular shape, the emitter tip may be formed in various shapes, such as a horn and a triangular pyramid. For example, the emitters 230 may be arranged on the cathode electrode 210 in such a manner as to be a predetermined distance apart from each other in the longitudinal direction and the traverse direction.

The emitter 230 may contain carbon-based material. Examples of the carbon-based material may include carbon nanotubes (CNTs), carbon nanowires, semiconductor nanowires, zinc oxide nanowires, carbon nanofibers, conductive nanorods, graphite, nanographene, and similar materials, but are not limited thereto.

However, in a case where the emitter 230 is realized as a carbon nanotube, the emitter 230 can obtain high-efficiency electric field emission properties unique to the carbon nanotube. For example, this carbon nanotube emitter 230 may be formed using various processes, such as laser vaporization, arc discharge, thermal-CVD, plasma-CVD, hot filament chemical vapor deposition (HF-CVD), but are not limited thereto.

Meanwhile, the emitter 230 may be provided on top of an electric field emission substrate 220. In this case, the electric field emission substrate 220 may be a normal wafer provided in such a manner that an electric field emission element includes an emitter. That is, the electric field emission substrate 220 is formed on top of the cathode electrode 210, and thus, the emitter 230 is mounted on the electric field emission substrate 220.

The gate electrode 240 is configured to regulate the flow of electrons, emitted from the emitter 230, according to a voltage being input. A portion, facing the plurality of emitters 230, of the gate electrode 240, that is, a portion, opposite the plurality of emitters 230, of the gate electrode 240, may include a mesh structure 241 with a conductive material (for example, a metal or the like). For example, the mesh structure 241 may employ a configuration in which thin metal wires are woven into a net shape in such a manner as to be spaced a distance apart from each other, or may employ a configuration in which a plurality of openings are formed in a metal plate. The gate electrode 240 may diffuse the electrons emitted from the emitter 230 while allowing the electron beams to pass through spaces between the metal lines in the mesh structure 241 or through the plurality of openings.

The gate electrode 240 contains a conductive material. For example, the gate electrode 240 may contain a metal, such as Al, Au, Ni, Ti, or Cr; transparent conductive oxide (TCO), such as indium tin oxide (ITO), indium zinc oxide (IZO), aluminum zinc oxide (AZO), or indium zinc tin oxide (IZTO); a conductive polymer; graphene; or similar material, but is not limited thereto.

An insulation layer (or an insulation spacer), which is not illustrated, may be positioned between the cathode electrode 210 and the gate electrode 240 around the plurality of emitters 230. At this point, the insulation layer is formed to have a thickness greater than a height of each of the plurality of emitters 230 in such a manner that the gate electrode 240 does not contact the plurality of emitters 230. The insulation layer can keep the gate electrode 240 insulated from the cathode electrode 210 and the plurality of emitters 230.

A low voltage (a negative voltage) is applied to the cathode electrode 210, or the cathode electrode 210 is connected to the ground. A high voltage (a positive voltage) of 5 kV or more may be applied to the anode electrode 300. In addition, a pulse voltage may be applied to the gate electrode 240. That is, a difference in voltage between the cathode electrode 210 and the gate electrode 240 forms an electric field around the plurality of emitters 230. This electric field causes the plurality of emitters 230 to emit electron beams. The emitted electron beams are accelerated by being attracted to the high voltage of the anode electrode 300. At this point, the pulse voltage of the gate

electrode 240 is a voltage having a high frequency or a low pulse width. For example, the pulse voltage may have characteristics of a high frequency of 100 kHz or higher. This pulse voltage makes high-speed switching of an electron beam possible and results in achieving an effect of lowering drive electric power.

As illustrated in FIGS. 5(a) and 5(b), the electron beam emission unit 200 may be formed without focusing electrodes 251, 252, or as illustrated in FIG. 6, the electron beam emission unit 200 may be formed to include at least one or more focusing electrode 251, 252, which is arranged over the gate electrode 240 in a manner that is spaced apart therefrom. For example, the first focusing electrode 251, which is arranged over the gate electrode 240 in a manner that is spaced apart therefrom, and the second focusing electrode 252, which is arranged over the first focusing electrode 251 in a manner that is spaced apart therefrom, may be provided.

The electron beam emission unit 200 may include a support body 242. The support body 242 is fixed to an edge of the mesh structure 241 corresponding to the plurality of emitters 230 and thus supports the mesh structure 241. In addition, a first insulation layer 261 may be positioned between the cathode electrode 210 and the support body 242 around the plurality of emitters 230.

The positioning of a second insulation layer 262 between the gate electrode 240 and the first focusing electrode 251 can insulate the gate electrode 240 and the first focusing electrode 251 from each other. The positioning of a third insulation layer 263 between the first focusing electrode 251 and the second focusing electrode 252 can insulate the first focusing electrode 251 and the second focusing electrode 252 from each other. Of course, the positioning of a fourth insulation layer (not illustrated) on top of the second focusing electrode 252 may insulate an upper portion of the second focusing electrode 252.

The second insulation layer 262, the first focusing electrode 251, the third insulation layer 263, the second focusing electrode 252, and the fourth insulation layer (not illustrated) have respective openings for allowing an electron beam to pass through. At this point, the second insulation layer 262 and the third insulation layer 263 may be formed to have the openings of the same size.

An opening 271 in the first focusing electrode 251 may be smaller in diameter than the entire mesh structure 241 of the gate electrode 240. An opening 272 in the second focusing electrode 252 may be smaller in diameter than the opening 271 in the first focusing electrode 251. Of course, an additional focusing electrode (not illustrated) may be provided over the second focusing electrode 252 in a manner that is spaced apart therefrom. In this case, an opening in the additional focusing electrode may be smaller in diameter than the opening 272 in the second focusing electrode 252. That is, the openings in the first focusing electrode 251 and the second focusing electrode 252 in this order (that is, in order in the upward direction) may be formed to gradually decrease in diameter.

A negative (minus) voltage may be applied to the first and second focusing electrodes 251 and 252. Accordingly, an electron beam passing through the mesh structure 241 of the gate electrode 240 passes through the opening 271 in the first focusing electrode 251 and then the opening 272 in the second focusing electrode 252. Thus, the electron beam can be focused by repulsive forces applied by the first and second focusing electrodes 251 and 252.

With this structure, the electron beam emission unit 200 has the advantage of having a simple inner structure, a compact size, and a low manufacturing cost. This advantage may be further distinct because the anode electrode 300, unlike in the prior art, is separately provided within the chamber 100.

That is, the electron beam emission unit 200, including the first and second focusing electrodes 251 and 252, can focus an electron beam and can reduce the size of the electron beam that is to reach the anode electrode 300. As a result, less metal debris can be generated, thereby lengthening the usage lifetime of the anode electrode 300.

The droplet generation device 400 is a device that injects a metal droplet D into the chamber 100. In particular, the droplet generation device 400 injects the metal droplet D into a space between the electron beam emission unit 200 and the anode electrode 300 within the chamber 100. Accordingly, an electron beam emitted from the electron beam emission unit 200 proceeds in an accelerated manner toward the anode electrode 300 and this accelerated electron beam is incident (irradiated) on the metal droplet D injected in the middle of a path along which the electron beam proceeds toward the anode electrode 300, thereby evaporating the metal droplet D. The metal droplet D, evaporated by the electron beam, is ionized, thereby generating plasma. Extreme ultraviolet (EUV) is generated in the plasma region surrounding the vicinity of the metal droplet D. That is, the plasma generated from the metal droplet D by the electron beam serves as a light source that generates extreme ultraviolet (EUV). The extreme ultraviolet light source generated in this manner can be output outside the chamber 100 through the exit 110 of the chamber 100.

That is, the metal droplet D may contain a metal radiative material that generates plasma when an electron beam is incident thereon. For example, a metal radiative material may contain one or more selected from the group consisting of Sn, Li, In, Sb, Te, Tb, Gd, and Al. For example, the droplet generation device 400 may be configured to drop the metal droplet D, such as Sn in a preset volume, according to a preset time cycle.

With reference to FIGS. 1 to 3, the multiplicity of electron beam emission units 200 may be provided. In this case, each of the electron beams generated in a multiplicity of the electron beam emission units 200 may proceed at a different angle or in a different direction toward at least one anode electrode 300. In addition, each of the electron beams may be output one by one or a plurality of electron beams may be output simultaneously.

That is, the multiplicity of electron beam emission units 200 may generate electron beams one after another in response to pulse drive by a gate voltage applied to each gate electrode 240. Alternatively, the multiplicity of electron beam emission units 200 may simultaneously generate electron beams according to pulse drive by a gate voltage applied to each gate electrode 240. In this case, for example, a control unit (not illustrated) may control the multiplicity of electron beam emission units 200 in such a manner that they generate electron beams one by one in respective turns or simultaneously generate a plurality of electron beams. Accordingly, each of the electron beams generated by the multiplicity of electron beam emission units 200 may be incident one by one on a region where the metal droplet D is present. Alternatively, a plurality of electron beams may be simultaneously incident on a region where the metal droplet D is present.

For example, with reference to FIGS. 1 to 3, each of the electron beam emission units 200 may be arranged on one side within the chamber 100, and the anode electrode 300 may be arranged on the other side within the chamber 100, that is, may be arranged on the side within the chamber 100, in which the exit 110 is positioned.

In this case, the anode electrode 300 is arranged on the other side within the chamber 100 in a manner that is positioned in the vicinity of the exit 110, with the exit 110 in the middle of the anode electrode 300. The anode electrode 300 may have an opening corresponding to the exit 110. That is, the anode electrode 300 may be arranged in the vicinity of the exit 110 on the other side within the chamber 100, and the opening in the anode electrode 300 may be arranged to correspond to the exit 110.

In particular, one side and the other side within the chamber 100 may have respective shapes of an arch that face each other. In this case, the anode electrode 300 may have a shape that corresponds to the arch shape of the other side within the chamber 100. With this structure, the anode electrode 300 can serve for intermediate focus (IF) of a multiplicity of EUV that are generated by each of the electron beams and proceed toward the other side within the chamber 100 to pass through the opening in the anode electrode 300.

That is, the multiplicity of EUV that are generated by each of the electron beams from the multiplicity of electron beam emission units 200 can be collected by electromagnetic repulsive force of the anode electrode 300 while passing through the opening in the anode electrode 300. Each of these electron beams, as illustrated in FIGS. 2 and 3, may be emitted one by one according to a drive pulse voltage applied to the gate electrode 240 of the corresponding electron beam emission unit 200. Alternatively, a plurality of electron beams, as illustrated in FIG. 1, may be simultaneously emitted according to a drive pulse voltage applied to the gate electrode 240 of the corresponding electron beam emission unit 200.

In addition, a reflection layer 500, which reflects EUV may be additionally provided within the chamber 100. For example, EUV generated by the incidence of any electron beam, may be output to the exit 110 in the chamber 100 after being reflected at least one time by the reflection layer 500, without being output directly to the exit 110 in the chamber 100. The application of this reflection function to the anode electrode 300 in the shape of an arch can collect each EUV, generated by the multiplicity of electron beams, toward the exit 110 in the chamber 100. Accordingly, the intensity of the EUV passing through the exit 110 can be increased.

To facilitate the smooth performing of this reflection function, the reflection layer 500 is arranged on one side within the chamber 100. The reflection layers 500 may be arranged around each of the electron beam emission units 200 positioned on one side within the chamber 100. Of course, the reflection layer 500 may also be arranged in the space between the respective electron beam emission units 200 spaced apart from each other.

In addition, the chamber 100 may be formed in such a manner that one side and the other side within the chamber 100 have respective shapes of an arch that face each other, and the reflection layer 500 may also be formed in the shape of an arch, corresponding to the arch shape of one side within the chamber 100. In this case, the above-described reflection function by the reflection layer 500 with respect to the EUV and the light collecting function by the anode electrode 300 in the shape of an arch on the other side within the chamber 100 with respect to the EVU are simultaneously performed in a complementary manner, thereby providing the advantage of improving the amount of output of extreme ultraviolet.

At this point, the reflection layer 500 has a reflection surface that is concaved in the direction toward the exit 110 in the chamber 100. For example, a multi-layer, formed by alternately stacking molybdenum (Mo) and silicon (Si), may be used as the reflection layer 500, but the reflection layer 500 is not limited thereto.

The specific embodiment of the present disclosure is described above, but various modifications may, of course, be made to the specific embodiment within the range that does not depart from the scope of the present disclosure. Therefore, the scope of the present disclosure is not limited to the embodiments which are described above and should be defined by the following claims and equivalents of the claims.

### INDUSTRIAL APPLICABILITY

According to the present disclosure, with the configuration as described above, an extreme ultraviolet (EUV) light source is generated based on an electron beam, but using an anode electrode that is formed separately from an electron beam emission unit. Therefore, the present disclosure provides the advantage of achieving a simple inner structure, a compact size, and a low manufacturing cost. In addition, according to the present disclosure, a low-power electron beam can be used when compared with a laser. Therefore, the present disclosure provides not only the advantage of reducing an adverse influence on an anode electrode, reducing debris or the like, and thus facilitating advantageous maintenance of the anode electrode, but also the effect of improving the amount of output of extreme ultraviolet through a plurality of electron beams. In addition, according to the present disclosure, a reflection function and a light collecting function with respect to an extreme ultraviolet light source are simultaneously performed in a complementary manner through the structure of a reflection layer in the shape of an arch on one side within a chamber, and through the structure of the anode electrode in the shape of an arch on the other side within the chamber. Thus, the present disclosure provides the advantage of improving the amount of output of extreme ultraviolet light.

1. A device for outputting extreme ultraviolet light source based on an electron beam and a metal droplet, the device comprising:
a chamber;
an electron beam emission unit including a cathode electrode and a plurality of emitters, each of which contains a carbon-based material and which are arranged over the cathode electrode in such a manner as to be spaced apart from each other, the electron beam emission unit generating an electron beam within the chamber;
an anode electrode positioned within the chamber, but in a manner that is spaced apart from the electron beam emission unit; and
a droplet generation device injecting a metal droplet into a space between the electron beam emission unit and the anode electrode within the chamber,
wherein, within the chamber, the metal droplet is ionized by the electron beam proceeding toward the anode electrode, thereby generating plasma, and extreme ultraviolet is generated from the plasma.

2. The light source device of claim 1, wherein a multiplicity of the electron beam emission units are provided, and
wherein each of the electron beams generated by the multiplicity of the electron beam emission units proceeds at a different angle or in a different direction toward the at least one anode electrode, wherein each of the electron beams is output one by one or a plurality of electron beams are output simultaneously.

3. The light source device of claim 2, wherein each of the electron beam emission units is arranged on one side within the chamber, and the anode electrode is arranged on the other side within the chamber where an exit for the extreme ultraviolet light source is positioned.

4. The light source device of claim 3, wherein the anode electrode is arranged on the other side within the chamber in a manner that is positioned in the vicinity of the exit, with the exit in the middle of the anode electrode, and the anode electrode has an opening corresponding to the exit.

5. The light source device of any one of claims 3 and 4, wherein one side and the other side within the chamber have respective shapes of an arch that face each other, and the anode electrode has a shape that corresponds to the arch shape of the other side within the chamber.

6. The light source device of any one of claims 3 and 4, further comprising:
a reflection layer arranged in the vicinity of the respective electron beam emission units on one side in the chamber, but also in the space between said respective electron beam emission units, to reflect the extreme ultraviolet.

7. The light source device of claim 6, wherein one side and the other side within the chamber have respective shapes of an arch that face each other, and the reflection layer has a shape that corresponds to the arch shape of one side within the chamber.

8. The light source device of claim 4, wherein the anode electrode serves for intermediate focus (IF) of a multiplicity of extreme ultraviolet light sources that are generated by the electron beams and pass through the opening in the anode electrode.

9. The light source device of claim 1, wherein each of the plurality of emitters has a pointed emitter tip and contains a carbon nanotube that is the carbon-based material.

10. The light source device of claim 1, wherein the electron beam emission unit further comprises:
a gate electrode arranged over the plurality of emitters in a manner that is spaced apart therefrom.

11. The light source device of claim 10, wherein a portion, facing the plurality of emitters, of the gate electrode has a mesh structure of a conductive material.

12. The light source device of claim 10, wherein the electron beam emission unit further includes at least one focusing electrode positioned over the gate electrode in a manner that is spaced apart from the gate electrode, and focusing the electron beam by a negative voltage being applied to the gate electrode.

13. The light source device of claim 12, wherein the focusing electrode includes a first focusing electrode and a second focusing electrode arranged over the first focusing electrode in a manner that is spaced apart from the first focusing electrode,
wherein the first and second focusing electrodes have respective openings facing each other, in such a manner as to allow the electron beam to pass through, and
wherein the opening in the second focusing electrode is smaller than the opening in the first focusing electrode.
